(19) United States
(12) Patent Application Publication
(10) Pub. No.: US 2026/0063679 A1
(43) Pub. Date: Mar. 5, 2026

(54) CURRENT MEASURING DEVICE

(71) Applicant: Infineon Technologies AG, Neubiberg (DE)

(72) Inventors: Thomas HAFNER, Magdalensberg (AT); Simone FONTANESI, Villach (AT); Gernot BINDER, Klagenfurt (AT); Johannes GÜTTINGER, Lind ob Velden (AT)

(21) Appl. No.: 19/308,814

(22) Filed: Aug. 25, 2025

(30) Foreign Application Priority Data
Sep. 5, 2024 (DE) 102024208473.5

(51) Int. Cl. G01R 15/20; G01R 19/00

(52) U.S. Cl. CPC G01R 15/205; G01R 19/0092

(57) ABSTRACT

A current measuring device has a current conductor and a differential magnetic field sensor. The differential magnetic field sensor has a connection frame and two sensor elements, wherein the sensor elements are arranged such in relation to an edge of a straight section of the current conductor, which is parallel to a direction of current flow through the current conductor, that one of the sensor elements overlaps the current conductor in a plan view of the current conductor and the other of the sensor elements does not overlap the current conductor in a plan view of the current conductor. The current measuring device further has a device for reducing distortions which are generated in an output signal of the differential magnetic field sensor due to eddy currents in the connection frame of the magnetic field sensor.

### CROSS REFERENCE TO RELATED APPLICATION

This application claims priority to Germany Patent Application No. 102024208473.5 filed on Sep. 5, 2024, the content of which is incorporated by reference herein in its entirety.

### TECHNICAL FIELD

The present disclosure relates to a current measuring device and in particular a current measuring device which has a differential magnetic field sensor for measuring a current through a straight section of a current conductor.

### BACKGROUND

In general, there is a need to measure a current which flows in an external conductor, such as in a conductor track of a PCB (printed circuit board) or in a busbar. In general, a differential xMR sensor chip can be used for this purpose. A differential concept is used to cancel homogeneous stray magnetic fields.

In typical semiconductor cases (or semiconductor packages), the sensor chip is fitted on an electrically conductive connection frame, which is also referred to as a lead frame, wherein the contact surfaces, also referred to as pads, of the connection frame, are connected to external connectors of the sensor chip. The element is finally overcast, potted, to protect it from threats such as mechanical impacts, chemical contaminants and the effect of light.

A connection frame may be disadvantageous in the case of current detection, since currents that change over time, such as fast transient signals, high-frequency AC signals or DC signals with a ripple, are accompanied by a magnetic field in the external conductor, which induces eddy currents in the connection frame. These unwanted eddy currents can degrade the measurement result. So, in the worst case, the eddy currents in the connection frame can lead to a degraded accuracy or an unwanted overcurrent reading.

To avoid eddy currents in a connection frame, current paths in the connection frame have hitherto been interrupted by deliberately removing conductive material of the connection frame. This is achieved by geometric features such as cutouts, slits, notches or cavities, typically in close proximity to the sensor elements. Such features are achieved by manufacturing processes such as punching, etching or laser cutting. This requires special tools that are only worthwhile for large-scale manufacturing. In addition, housing re-qualification is necessary if the standard connection frame geometry is replaced. However, in order to speed up the development roadmap, it may be desirable to reuse existing cases with specified connection frame solutions.

Therefore, there is a need for current measuring devices which enable accurate detection of a current through a conductor without changing a connection frame.

According to the present disclosure, this is achieved by a current measuring device which has the following features: a current conductor, a differential magnetic field sensor which has a connection frame and two sensor elements, wherein the sensor elements are arranged such in relation to an edge of a straight section of the current conductor, which is parallel to a direction of current flow through the current conductor, that one of the sensor elements overlaps the current conductor in a plan view of the current conductor and the other of the sensor elements does not overlap the current conductor in a plan view of the current conductor, and a device for reducing distortions which are generated in an output signal of the differential magnetic field sensor due to eddy currents in the connection frame of the magnetic field sensor.

In examples, the device for reducing distortions has a layer made from an electrically conductive non-magnetic material which is arranged on the side of the connection frame facing the current conductor. This layer constitutes a compensation layer and can be considered an eddy current filter for compensating eddy current generation in the connection frame of a cased sensor IC (IC=integrated circuit). It was recognized that in such a layer, which is made from an electrically conductive non-magnetic material and which can be arranged at least to some extent between the current conductor and the sensor chip, eddy currents can be generated which generate a magnetic field which is opposed to a magnetic field that is generated by eddy currents in the connection frame. Thus, it is possible to reduce influences on the measuring signal that are due to eddy currents generated in the connection frame.

In examples, the device for reducing distortions has a hole through the current conductor, wherein the edge of the straight section of the current conductor, in relation to which edge the sensor elements are arranged, is formed by the hole through the current conductor, wherein the other of the sensor elements is arranged above the hole in a plan view of the current conductor. The hole penetrates the current conductor, that is to say is completely surrounded by material of the current conductor in a plan view. The edge, in relation to which the sensor elements are arranged, therefore constitutes an inner edge of the current conductor. It was recognized that in a conductor which should be used to measure the current, such a hole or such an opening can be used to suppress vertical magnetic field components at the location of the magnetic field sensor which are responsible for generating eddy currents in the connection frame. Thus, the influence of such eddy currents on the measuring signal can be reduced.

### BRIEF DESCRIPTION OF THE DRAWINGS

Examples of the present disclosure are described in more detail below with reference to the attached drawing. In the figures:

FIG. 1A shows a schematic perspective view of an example of a cased sensor chip and a current conductor;

FIG. 1B shows a schematic plan view of the sensor chip of FIG. 1A;

FIGS. 2A and 2B show simulation results which show magnitude and phase of simulated magnetic field measurements, assuming that no eddy currents occur in the connection frame;

FIGS. 2C and 2D show simulation results which show magnitude and phase of simulated magnetic field measurements under the influence of eddy currents in the connection frame;

FIG. 3 shows a schematic perspective view of an example of a current measuring device according to the present disclosure;

FIG. 4 shows a schematic cross-sectional illustration of an example of a current measuring device according to the present disclosure;

FIGS. 5A-5C, 6A-6C, 7A-7C, and 8A-8C show schematic plan views and simulation results of examples of current measuring devices with compensation layers according to the present disclosure;

FIGS. 9A to 9C show simulation results for illustrating the effect of an example of the present disclosure on a current measurement;

FIGS. 10A to 10M show schematic plan views of examples of current measuring devices with differently structured compensation layers;

FIG. 11A and FIG. 11B show a schematic perspective view and a plan view of an example of a current measuring device with a hole in the current conductor;

FIG. 12 shows a schematic representation of magnetic field lines of an example of a current conductor which has a hole; and

FIG. 13A and FIG. 13B show simulation results which show the magnitude and phase of simulated magnetic field measurements using a current measuring device as shown in FIGS. 11A and 11B.

### DETAILED DESCRIPTION

Below, examples of the present disclosure are described in detail and using the attached drawings. It is pointed out that identical elements or elements having the same functionality are provided with identical or similar reference signs, a repeated description of elements provided with identical or similar reference signs typically being omitted. In particular, identical or similar elements may each be provided with reference signs which have the same number with a different or no lower case letter. Descriptions of elements having identical or similar reference signs are mutually interchangeable. In the following description, many details are described in order to yield a more thorough explanation of examples of the disclosure. However, it is evident to those skilled in the art that other examples may be implemented without these specific details. Features of the various examples described may be combined with one another, unless features of a corresponding combination are mutually exclusive or such a combination is expressly excluded.

The dimensions and measurements mentioned in the following description of the figures are to be understood purely by way of example. They are only used to give an approximate insight into the size relationships wherein the innovative concept, which is described here, is realized. In the figures, elements may be illustrated semi-transparently at least to some extent, so as not to hide elements located beneath or behind them for the purposes of explaining the disclosure. When overlapping is discussed here, this means overlapping in a plan view of the current conductor, e.g., as seen in the vertical direction, unless explicitly stated otherwise.

The graphs, which here show simulation results, in each case show the difference of the magnetic fields detected by both magnetic field sensor elements, wherein these magnetic fields in the figures are referred to as BxRight for the magnetic field detected by the right sensor element in the illustrations and BxLeft for the magnetic field detected by the left sensor element in the illustrations.

Insofar as compensation is discussed in the context of this disclosure, this can be understood to mean a complete cancellation, but also a weakening that has taken place to a certain extent. If compensation of a magnetic field due to eddy currents is discussed for example in the context of this disclosure, this can be understood to mean a complete cancellation of this magnetic field, but also a weakening of this magnetic field that has taken place to a certain extent.

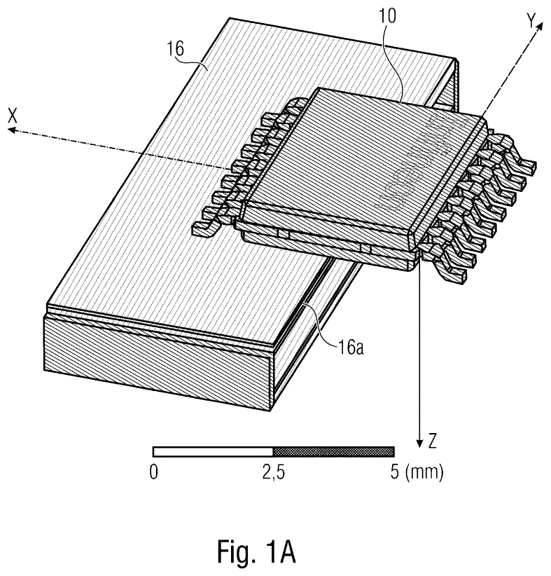

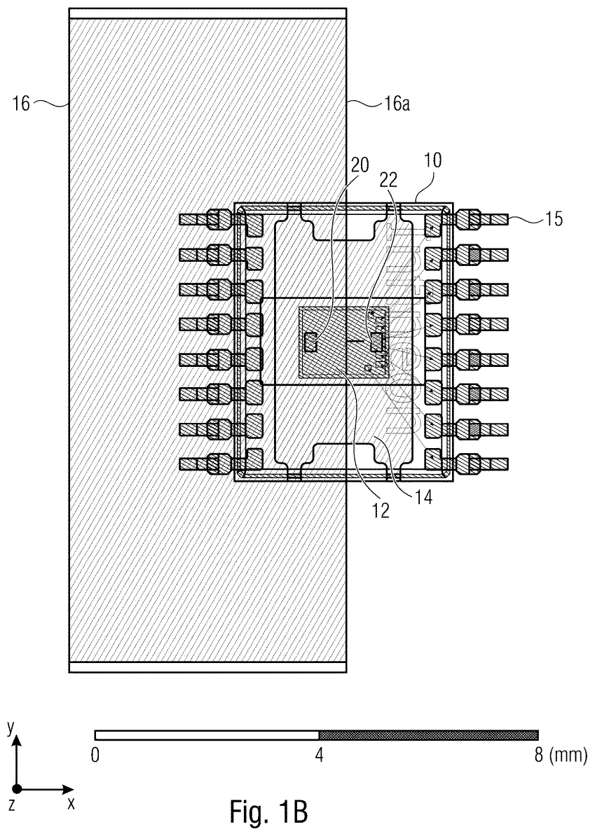

FIG. 1A schematically shows a cased differential magnetic field sensor 10. The cased sensor 10 has, as shown in FIG. 1B, a sensor chip 12, for example in the form of an integrated circuit, and a connection frame 14. The sensor chip 12 is arranged on the underside of the connection frame 14 facing a current conductor 16. The current conductor 16 is straight over the entire length that has an influence on the detection of the magnetic field. A straight section of a current conductor can here be understood to mean a section of a current conductor, the beginning and end of which can be connected by a straight line arranged in the current conductor.

The connection frame has a chip connection surface in a conventional manner, which is also referred to as a chip pad, on which the sensor chip 12 is fitted. Furthermore, the magnetic field sensor has external connector legs 15. The connector legs 15 can be used in a conventional manner to supply power and transmit signals, for example control signals and sensor output signals. The connector legs 15 can be connected in a conventional manner to connection surfaces of the sensor chip 12 using the connection frame, for example using bond wires. The sensor chip 12 and the connection frame 14, as well as the connector legs 15 are cased with each other to form an integrated component from which the connector legs protrude. A potting compound can for example be used for casing. At this point it should be noted that in FIG. 1B, the components are illustrated transparently to some extent, so that the parts that are relevant for this description are visible.

The sensor chip 12 has two sensor elements 20 and 22. The sensor elements are magnetoresistive sensor elements which are also referred to in abbreviated form as xMR sensors. These for example include TMR sensors (tunnel magnetoresistance), AMR sensors (anisotropic magnetoresistance), GMR sensors (giant magnetoresistance), CMR sensors (colossal magnetoresistance) and the like. In principle, the electrical resistance or conductance of magnetoresistive sensors changes when the sensor is exposed to a magnetic field. In principle, xMR sensors in this case recognize the field strength parallel to a reference direction. This is implemented by way of a resistance-based measurement using different magnetoresistive sensor elements. The sensor elements output an output signal which depends on the magnetic field in the direction in which they are sensitive in each case and indicates the current flowing through the current conductor 16.

The current conductor 16 can be a conductor track on a printed circuit board and consist of a conductive material, such as copper. The current conductor may also have a plurality of layers, e.g., conductor tracks that are arranged above one another, in the printed circuit board, such as two layers that are arranged above one another, as shown in FIG. 1A. Insulating layers can be arranged between the various conductor planes. A current flows through the current conductor in a direction which corresponds to the longitudinal direction of the current conductor, which is referred to as the Y direction here. The sensor chip 12 is arranged relative to the current conductor 16 above an edge 16a of the current conductor such that one of the sensor elements, sensor element 20, completely overlaps the current conductor 16, while the other of the sensor elements, sensor element 22, does not overlap the current conductor. The sensor chip 12 is configured to generate the differential signal of the two sensor elements, in which homogeneous magnetic fields are canceled. Preferably, the sensor chip 12 is arranged symmetrically to the edge 16a above the current conductor 16, e.g., each of the sensor elements is spaced an equal distance from the edge 16a and a virtual line that connects the two sensor elements 20 and 22 stands perpendicularly on the edge 16a.

The sensor elements 20 and 22 are configured and arranged to measure a magnetic field in one direction which is transverse to the direction of current flow through the conductor 16, which is here referred to as the X direction. Accordingly, the sensor elements 20 and 22 are arranged at positions where the current flow through the current conductor generates a corresponding magnetic field in the sensitive direction of the sensor elements. The vertical direction, the Z direction, is perpendicular to the direction of current flow and the magnetic field measurement direction. In other words, the vertical direction is perpendicular to a plane which is spanned by the direction of current flow and the sensitive direction. The vertical direction corresponds to a plan view direction of the current conductor.

The cased sensor 10 is mounted or fitted in a stationary manner relative to the current conductor 16 in order to detect the magnetic field in a direction transverse to the direction of flow of the current which flows through the current conductor 16 and generates the magnetic field.

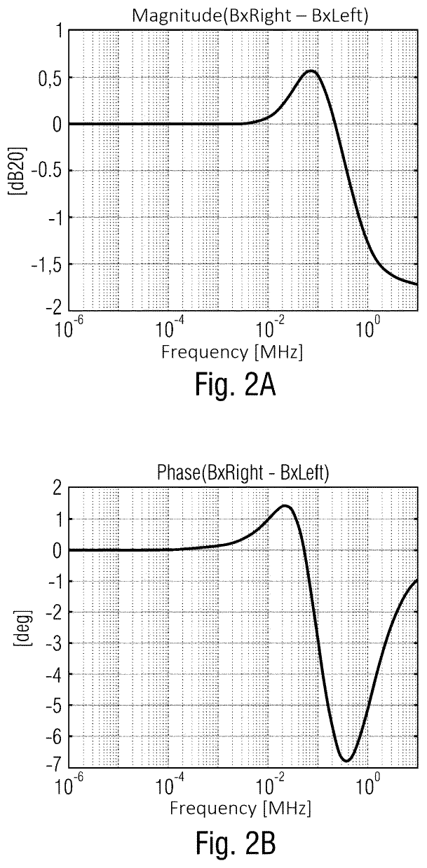

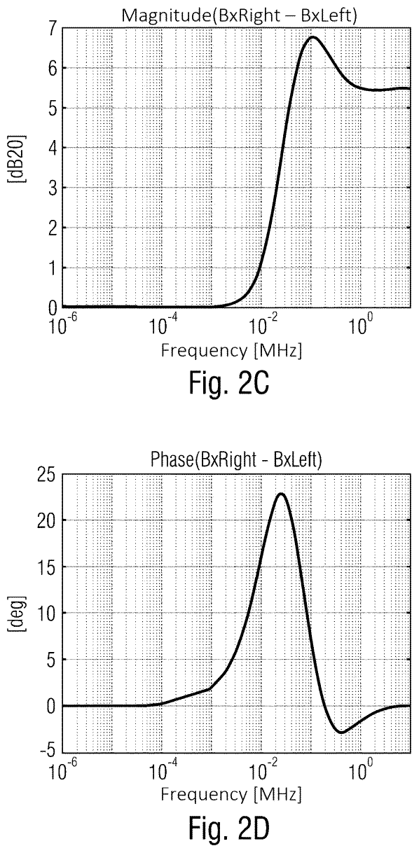

FIGS. 2A and 2B show the magnitude and phase of simulated magnetic field measurements assuming a non-conductive connection frame, e.g., assuming that no skin effects, e.g., eddy currents, occur in the connection frame. Here, skin effects only occur in the current conductor 16. The graphs thus represent the transfer characteristics of magnitude and phase over the frequency. Without skin effects in the current conductor 16, the transfer characteristics of both magnitude and phase would be straight lines, e.g., constant. In the simulations, a track width of the current conductor of 5 mm, a chip thickness of the sensor chip of 150 μm and a distance between the sensor elements of 1.2 mm were assumed.

FIGS. 2C and 2D show corresponding transfer characteristics for a sensor chip with an electrically conductive connection frame, as shown for example in FIGS. 1A and 1B. The differences in the transfer characteristics in FIGS. 2A and 2B are due to eddy currents which are generated in the connection frame. As can be seen in FIG. 2C, this results in a high signal amplification at high frequencies. Furthermore, higher phase deviations also result, as can be seen in FIG. 2C.

Changes in the current through the current conductor and magnetic field changes caused by these changes thus induce eddy currents in the connection frame, which in turn lead to a magnetic field which is measured by the sensor chip, which leads to distortions of the current measured by the sensor chips.

Examples of the present disclosure aim to reduce such distortions by providing a device to compensate magnetic fields generated in the connection frame by such eddy currents or by reducing the generation of such eddy currents in the connection frame. As described here, such a device can be implemented in various ways.

In examples, an eddy current filter is provided on a side of the connection frame facing the current conductor, in particular between the current conductor and the sensor. The filter is configured to reduce, and in the optimum case to compensate, eddy current generation in the connection frame and/or the effect of such eddy current generation in the connection frame of a cased sensor chip. Such a filter can be formed by a layer made from an electrically conductive non-magnetic material. In examples, the material may be copper or aluminum. In examples, the layer may be part of a metallization plane, for example a copper plane on a PCB.

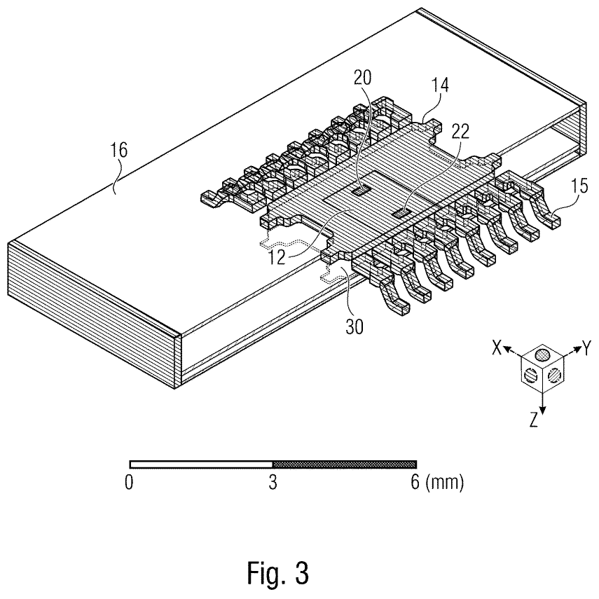

FIG. 3 shows an example of a current measuring device according to the present disclosure. The current measuring device has a current conductor 16 and a differential magnetic field sensor. These may be formed by a current conductor and a magnetic field sensor, as described above with reference to FIGS. 1A and 1B, so that in this respect, reference is also made to the above description. Such a current measuring device is suitable for detecting a current in a current conductor using a differential sensor, wherein the connection frame 14 and the sensor chip 12 of the cased sensor are only shown schematically in FIG. 3. The current measuring device shown in FIG. 3 has a layer 30 made from an electrically conductive non-magnetic material, which is arranged on the side of the sensor chip 12 facing the current conductor 16. Since the sensor chip 12 is arranged on the side of the connection frame facing the current conductor 16, the layer 30 is arranged on the side of the connection frame 14 facing the current conductor 16 and the sensor chip is arranged between the connection frame 14 and layer 30. The layer 30 may have a shape corresponding to the connection frame 14, so that the layer 30 completely overlaps the connection frame 14. The layer 30 is provided to reduce or compensate the influence of eddy currents in the sensor IC connection frame 14 and can thus be referred to as a compensation layer.

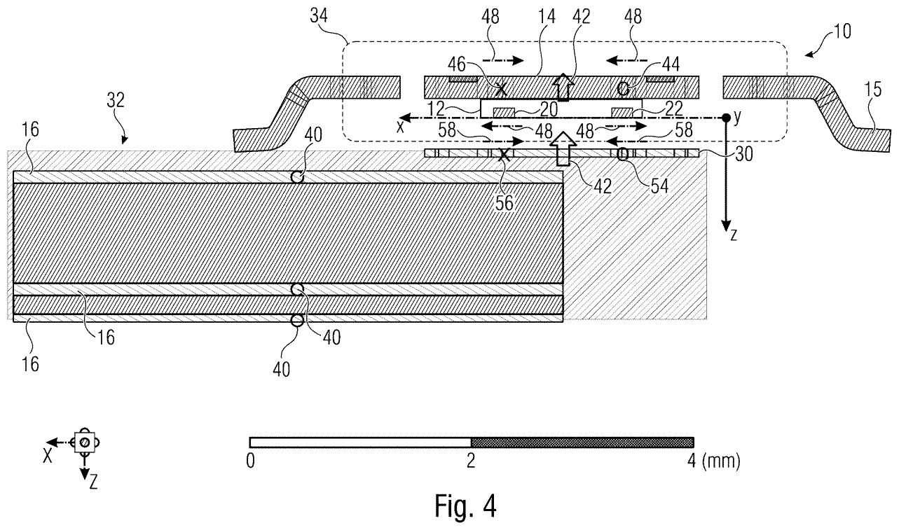

The current measuring device thus has a cased sensor IC, for example the sensor 10, a current-carrying conductor, for example the current conductor 16, and an additional layer between the sensor and current conductor, which can be formed by a busbar, which influences the formation of eddy currents which are generated in the connection frame of the sensor. FIG. 4 shows a schematic cross-sectional illustration of the current measuring device with connection frame 14, sensor chip 12, current conductor 16 and compensation layer 30. In the example shown, the current conductor 16 is formed by three planes of a PCB 32, wherein it is clear however that the current conductor can be formed by a single layer or a different number of layers of a PCB. Electrically insulating material, for example an epoxy resin or a dielectric, is provided between the planes of the current conductor. The compensation layer 30 can be formed by a fourth metallization plane of the PCB, for example a structured copper layer, other parts of which can also be used for connecting connector legs 15 of the cased sensor 10. As can be seen in FIG. 4, the connector legs 15 can be bent in a usual manner and the sensor chip 12 with connection frame 14 can be encased by a potting compound 34, which is indicated by a dashed line. In examples, the thickness of the compensation layer 30 may correspond to a standard metallization thickness, e.g., copper thickness, of PCBs.

A current flows through the current conductor 16 in the Y direction, out of the plane of projection in FIG. 4, as is indicated by corresponding circles 40. This current flow generates a vertical stray field 42 in the Z direction, as indicated by corresponding arrows in FIG. 4. Eddy currents 44 and 46 are generated in the connection frame 14 by this vertical stray field, of which, eddy current 44 flows out of the plane of projection and eddy current 46 flows into the plane of projection. A magnetic stray field 48 is generated by these eddy currents 44 and 46, which stray field has components in the X direction, as shown by corresponding arrows in FIG. 4. Eddy currents 54 and 56 are also generated in the compensation layer 30 by the vertical stray field 42, of which, eddy current 54 flows out of the plane of projection and eddy current 56 flows into the plane of projection. These eddy currents 54 and 56 in turn cause a magnetic stray field 58. The magnetic stray fields 48 and 58 are opposed to each other in the region of the sensor chip 12 in the sensitive direction, e.g., the detection direction, of the sensor and thus superposed in a destructive manner. In examples, the eddy currents in the connection frame 14 and in the compensation layer 30 generate a magnetic field, which is ideally canceled in the region of the sensor elements, so that the influence of eddy currents induced in the connection frame is fully compensated. Thus, distortions of the magnetic field to be detected due to eddy currents in the connection frame and thus distortions in the output signal of the magnetic field sensor, e.g., the current measurement, can be reduced and at best avoided.

In examples, the sensor elements of the magnetic field sensor are arranged on the side of the connection frame facing the current conductor and the compensation layer is arranged on the side of the sensor elements facing the current conductor. In examples, the compensation layer is arranged parallel to the current conductor, e.g., the main surfaces (largest surfaces in terms of area) of the compensation layer and the current conductor extend parallel to each other. In other words, the plane in which the compensation layer is formed is parallel to the plane in which the current conductor is formed.

In examples, the thickness of the compensation layer, e.g., the dimensioning of the compensation layer in the vertical direction is smaller than the thickness of the connection frame. This makes it possible to allow for the fact that the vertical stray magnetic field at the location of the compensation layer is higher than the vertical stray magnetic field at the location of the connection frame. This is the case because the compensation layer is closer to the current conductor than the connection frame. Thus, it is possible to achieve better compensation of the lateral stray magnetic fields generated by the eddy currents.

In examples, the compensation layer may have no external connector and therefore no fixed reference potential. In examples, the compensation layer can be connected to a fixed reference potential, e.g., ground.

In examples, the compensation layer is arranged, at least in sections, between the connection frame and the current conductor. In examples, the compensation layer is arranged such that it overlaps the connection frame completely in a plan view.

In examples, the compensation layer is formed to generate eddy currents in same using a magnetic field which is generated by the current through the current conductor, which eddy currents generate a magnetic field in the sensitive direction of the magnetic field sensor, which magnetic field counteracts the magnetic field in the sensitive direction of the magnetic field sensor, which is generated by eddy currents in the connection frame. In examples, similar eddy currents are generated in the compensation layer as in the connection frame. Thus, the stray fields of the eddy currents at the positions of the sensor elements can be canceled or at least greatly reduced.

In examples, the compensation layer is configured to attenuate the magnetic fields from the busbar less at higher frequencies in that eddy currents with a small radius are interrupted by slits or openings in the compensation layer below the sensor elements.

In examples, the size and shape of the compensation layer are configured to achieve a compromise between amplitude and phase compensation.

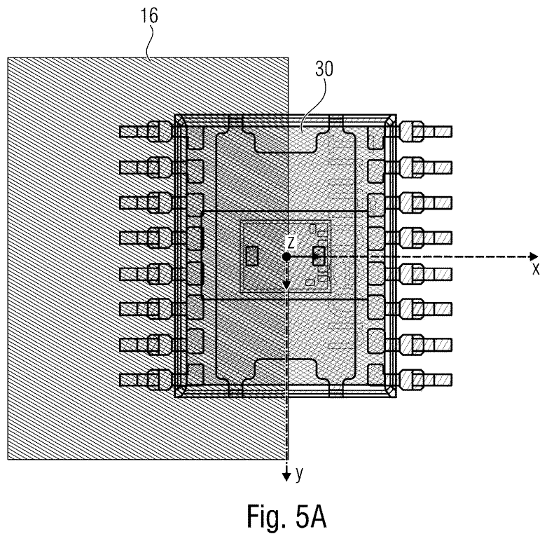

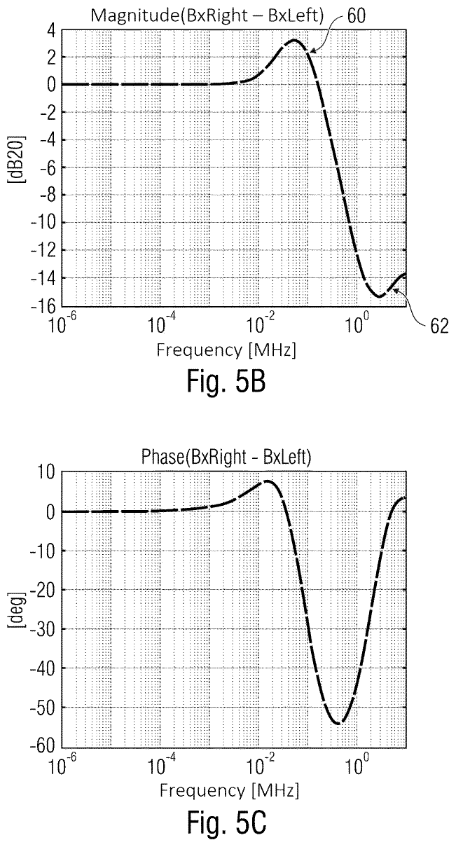

Examples of shapes and sizes of compensation layers are explained in more detail below with reference to FIGS. 5 to 10. However, it is not necessary to explain further that the shapes and sizes described below are merely example and not final and that further variation of parameters of same are possible. At this point, it should be noted that FIGS. 5 to 10 are purely schematic and are used to show shapes and structures of the compensation layers. These figures may give the impression that the compensation layer is arranged above the sensor chip and the connection frame to some extent, which is actually not the case, since the elements are arranged in the following order in the vertical direction: current conductors, above them the compensation layer, above that the sensor chip and above that the connection frame.

FIG. 5A shows an example of a full-surface compensation layer 30, which essentially overlaps the cased sensor chip completely, with the exception of the connector legs.

Alternatively, this compensation layer could also have the shape shown in FIG. 3, which would hardly influence the effect. FIG. 5B and FIG. 5C show the simulated magnitude and the simulated phase of the magnetic field detected by the magnetic field sensor if the compensation layer 30 shown in FIG. 5A is present. A comparison of FIG. 5B with FIG. 2C clearly shows a smaller deviation of the magnitude, the amplification 60, due to the compensation by the compensation layer, namely from almost 7 dB20 without compensation layer to about 3 dB20 with compensation layer. However, there is a greater attenuation 62 at higher frequencies due to the compensation layer. In examples, the compensation layer shown in FIG. 5A, which can be referred to as a copper shield, can effect an amplification of the field at the left sensor element, which is arranged above the current conductor and overlaps same, and an attenuation at the right sensor element, which does not overlap the current conductor.

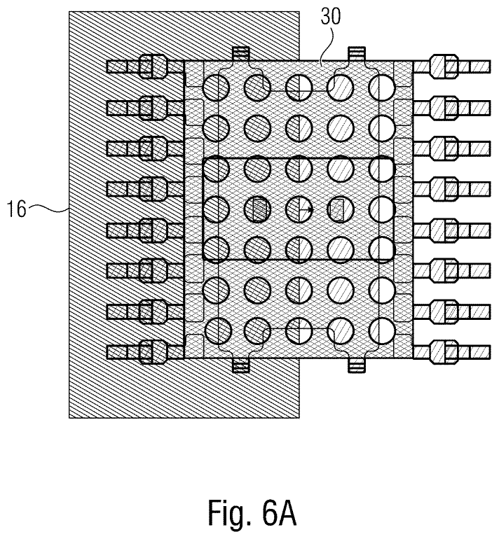

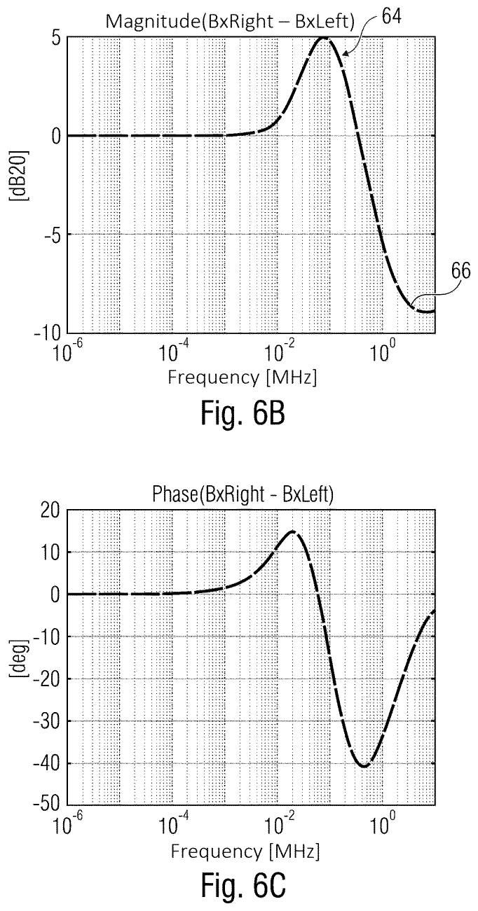

FIG. 6A shows an example of a compensation layer 30, which in turn is formed such that it overlaps the cased sensor completely and is provided with round through holes. In the example shown, 35 holes are provided in a regular grid. In the example shown, the diameter of the holes is 400 μm. However, it is obvious that a different number of holes may be provided in a regular or irregular grid. Furthermore, the holes may have different diameters, e.g., in a range of 100 to 700 μm and may have the same or different sizes. The larger the proportion of the surface area that is holes, the lower the attenuation at high frequencies is expected to be. In examples, two of the holes may be arranged directly above the two sensor elements. FIGS. 6B and 6C show the simulated magnitude and the simulated phase of the magnetic field detected by the magnetic field sensor if the compensation layer 30 shown in FIG. 6A is present. Thus, FIG. 6B shows a somewhat increased amplification 64 compared to FIG. 5B, but an attenuation 66 that is lower by approximately 6 dB20. In examples of the present disclosure, the compensation layer 30 thus has a multiplicity of the same penetrating holes, the number of which may be between 10 and 50 and which may be arranged in a regular or irregular grid.

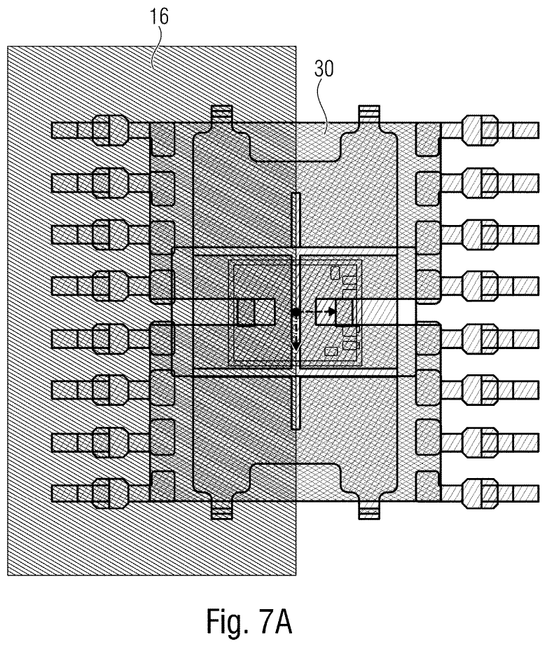

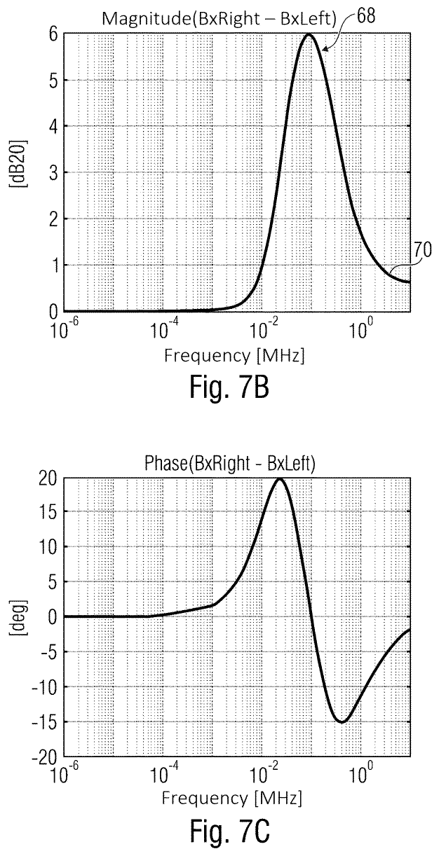

FIG. 7A shows an example of a compensation layer 30 in a butterfly shape. The butterfly shape has two wings which are defined by slits running from the outside to the inside transversely to the direction of flow of current, which slits end before the center, so a central web remains. The two slits are arranged above the two sensor elements. In the example shown, cross-shaped slits also extend in each case into the two wings of the butterfly shape starting from the center point of the central web. FIGS. 7B and 7C show the simulated magnitude and the simulated phase of the magnetic field detected by the magnetic field sensor if the compensation layer 30 shown in FIG. 7A is present. FIG. 7B shows that the amplification 68 is only slightly reduced here, but the attenuation 70 is reduced considerably.

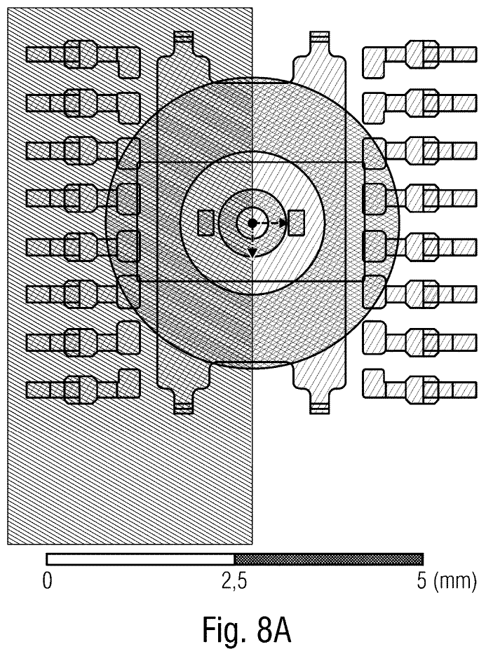

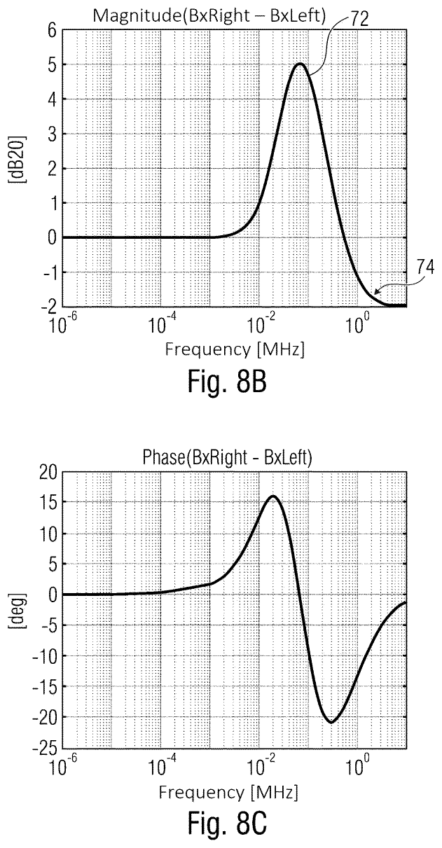

FIG. 8A shows an example of a compensation layer 30 which is formed by concentric rings, two concentric rings in the example shown. In other words, the compensation layer 30 has a round outer shape and an annular break, which is arranged concentrically in relation to a round central break in the compensation layer 30. Two sections of the annular break, which are opposite one another across the center of the compensation layer, are arranged above the two sensor elements. FIGS. 8B and 8C show the simulated magnitude and the simulated phase of the magnetic field detected by the magnetic field sensor if the compensation layer 30 shown in FIG. 8A is present. FIG. 8B shows that the amplification 72 is reduced, while the attenuation is reduced due to the opening.

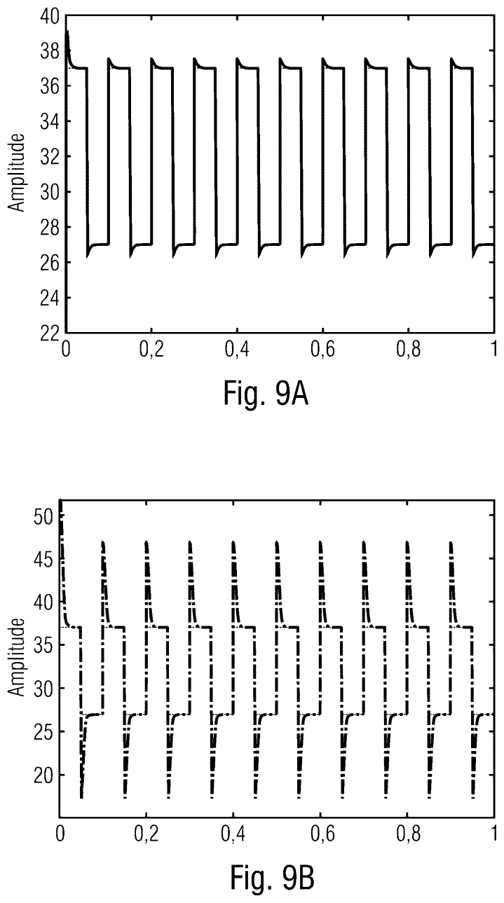

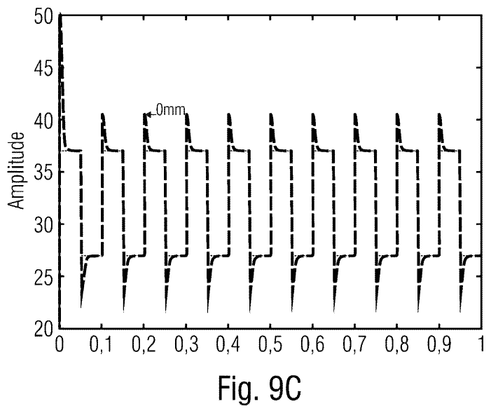

FIGS. 9A to 9C show a comparison of simulated time domain signals for an ideal connection frame without induced eddy currents in FIG. 9A, a real connection frame in which eddy currents are induced in FIG. 9B, and an example of a device according to the present disclosure with a compensation layer in FIG. 9C. The compensation layer is a simple copper layer below the sensor chip, as shown in FIG. 5. Here, the positive effect on the overshoot behavior, which is strongly attenuated due to the compensation layer, can be seen clearly.

The simulation was based on an input current with a DC component of 32 A and a ripple with a frequency of 10 kHz and an amplitude of 5 A.

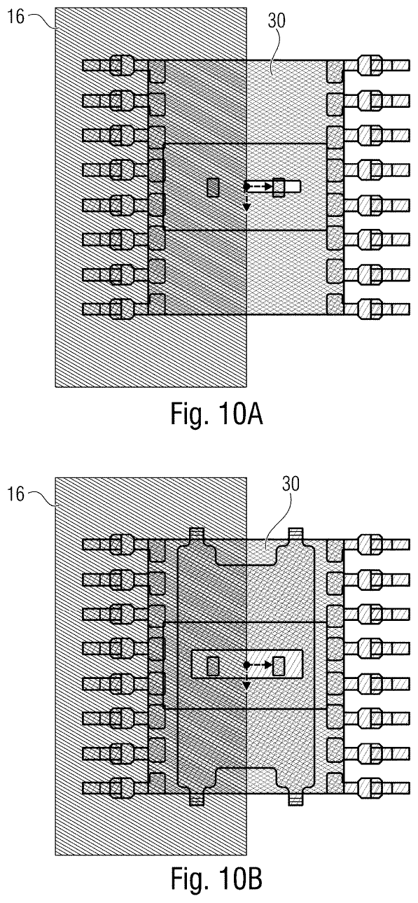

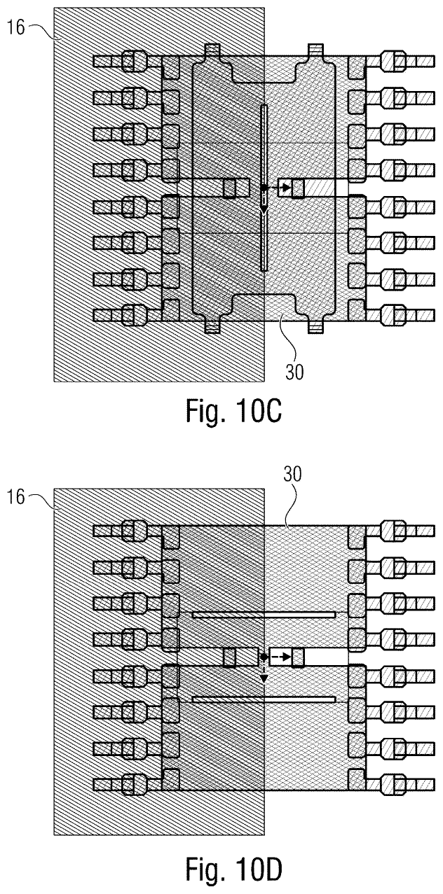

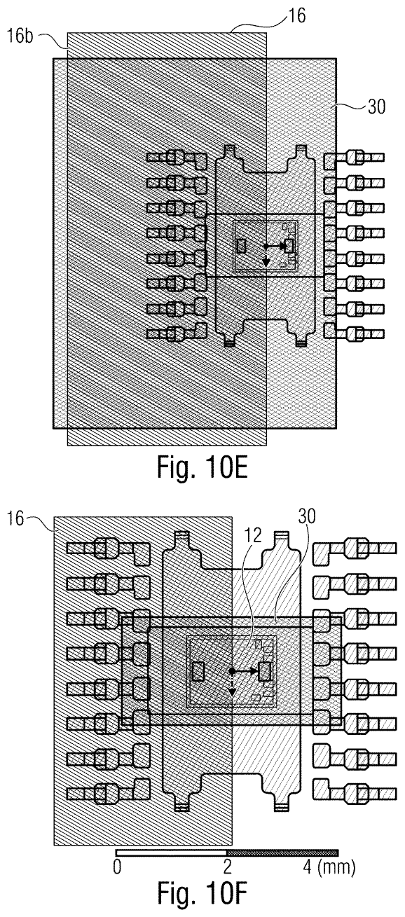

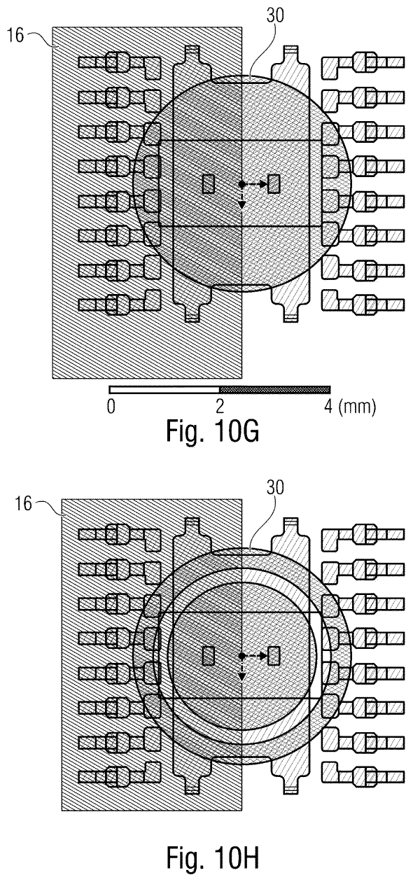

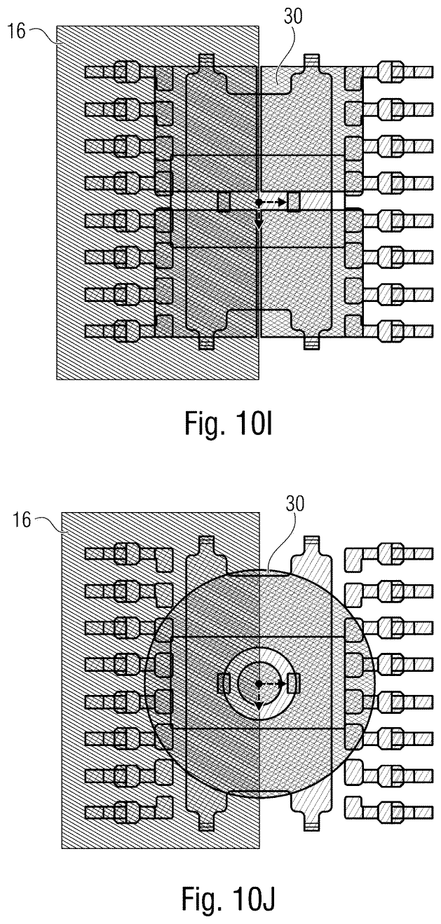

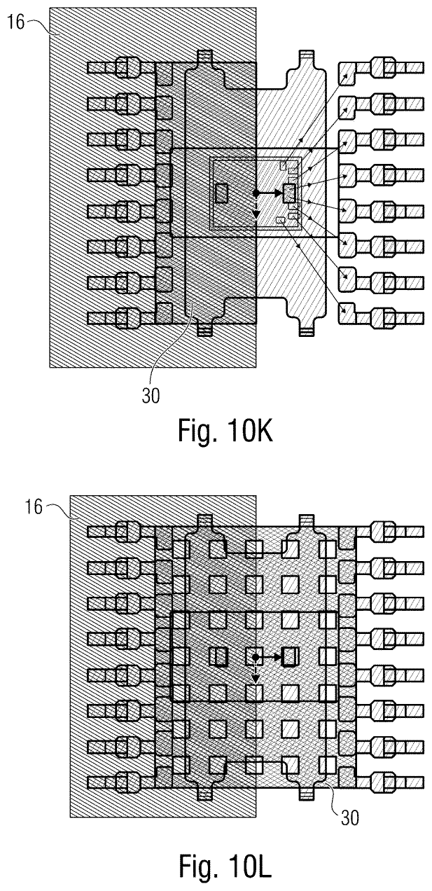

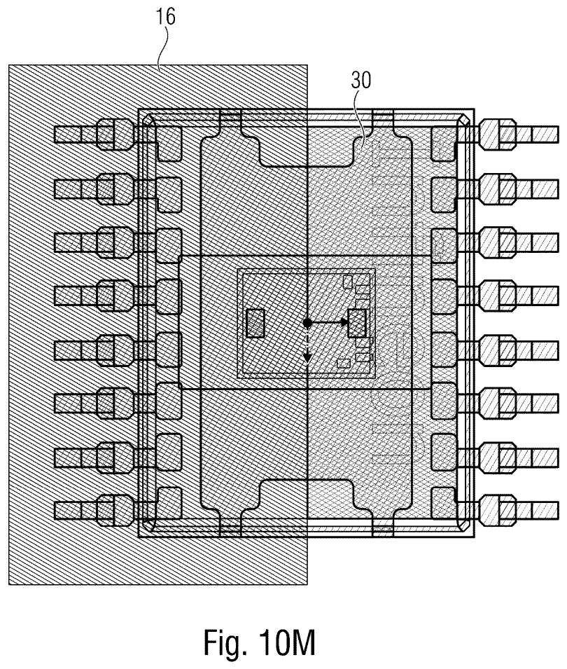

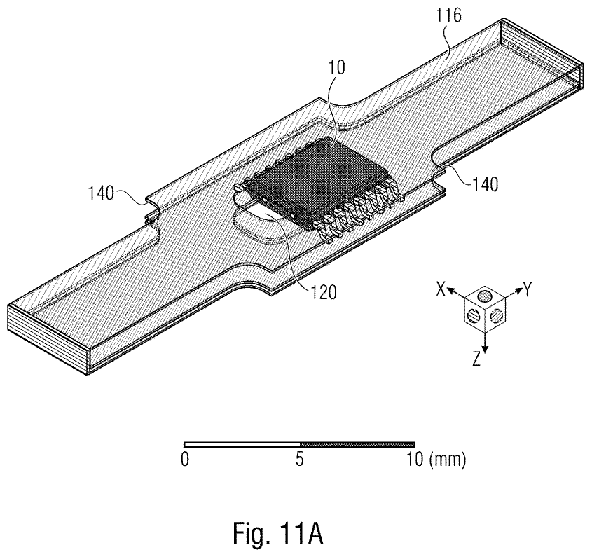

Further examples of possible compensation layers are shown in FIGS. 10A to 10M. Simulations have shown that the influence of magnetic fields which are generated by eddy currents in the connection frame can also be reduced or compensated optimally by these compensation layers.

FIG. 10A shows a compensation layer 30, which has only a small break above the sensor element, which does not overlap the current conductor and is otherwise formed completely under the cased sensor. The width of the slit is somewhat smaller than the size of the sensor element in the direction of the width of the slit, so that it does not completely overlap the sensor element.

FIG. 10B shows a compensation layer 30, like FIG. 10A, but with the difference that a break in the compensation layer is formed by a slit which has a length and width in order to overlap both sensor elements completely.

FIG. 10C shows a compensation layer 30 in a butterfly shape, which differs from the compensation layer shown in FIG. 7A in that the slits which extend into the two wings of the butterfly shape are not cross-shaped, but merely rod-shaped, extending perpendicularly away from the central web.

FIG. 10D shows a compensation layer 30 in a butterfly shape, this differs from the compensation layer shown in FIG. 7A in that no cross-shaped slits are formed in the two wings starting from the center point of the central web, but rather only the cross webs of the cross-shaped slits, e.g., slits which extend in the same direction as the slits which define the central web, are formed. The central web can therefore be narrower than in the examples shown in FIGS. 7A and 10C.

FIG. 10E shows a compensation layer 30, which is larger in a plan view of the current conductor 16 and the compensation layer 30 than the cased sensor with the connection frame, wherein the compensation layer 30 is enlarged in the direction of the opposite edge 16b of the current conductor 16 and extends up to or beyond this opposite edge 16b.

FIG. 10F shows a compensation layer 30 which, compared to the compensation layer 30 shown in FIG. 5A, has a reduced size in the longitudinal direction of the straight current conductor 16, e.g., the direction of current flow. The compensation layer 30 shown in FIG. 10F does not extend over the entire length of the connection frame in this direction, but is limited to an area in which the sensor chip 12 is arranged.

FIG. 10G shows a compensation layer 30 which is formed as a fully filled circle in a plan view, which is arranged centrally above the sensor chip and has a diameter to cover the sensor chip and essential parts of the connection frame.

FIG. 10H shows a compensation layer 30 which differs from the compensation layer in FIG. 10G in that the circle is not filled completely, but has a concentric annular break.

FIG. 10I shows a compensation layer 30 which differs from the compensation layer shown in FIG. 5A in that it has a continuous slit transversely to the direction of current flow through the current conductor 6, which extends over the two sensor elements of the magnetic field sensor.

FIG. 10J shows a compensation layer 30 which differs from the compensation layer in FIG. 10H in that the concentric annular break is formed in such a way that the compensation layer exposes both sensor elements of the magnetic field sensor completely or to some extent.

FIG. 10K shows a compensation layer 30 which differs from the compensation layer 30 shown in FIG. 5A in that it is formed only in a region of the cased sensor which overlaps the current conductor 16, while it is not formed in the region of the cased sensor which does not overlap the current conductor 16.

FIG. 10L shows a compensation layer 30 which differs from the compensation layer shown in FIG. 6A in that the through openings have a square instead of a round cross section.

FIG. 10M shows a compensation layer 30 which differs from the compensation layer 30 shown in FIG. 5A in that it is formed only in a region of the cased sensor which does not overlap the current conductor 16, while it is not formed in the region of the cased sensor which overlaps the current conductor 16.

In the examples described above with reference to FIGS. 3 to 10, the device for reducing distortions due to eddy currents in the connection frame is formed by a compensation layer. In other examples, the device may be formed by a hole in the form of a continuous opening in the current conductor, the current of which should be detected.

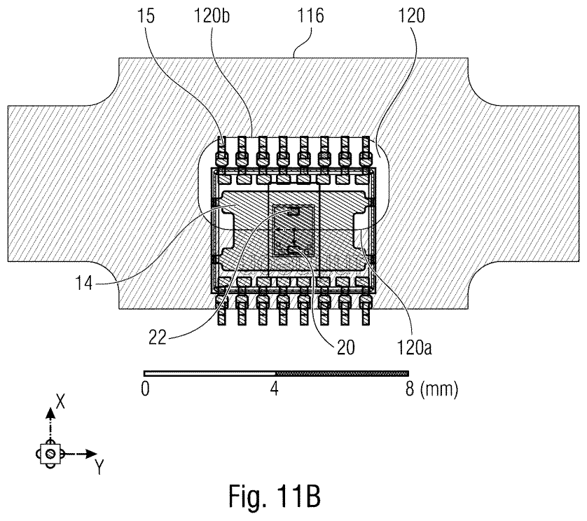

One example of a current measuring device according to the present disclosure is shown in FIGS. 11A and 11B. The current measuring device has a current conductor 116 in which a hole 120 is formed as a recess which penetrates the current conductor 116 completely. The cased sensor is arranged and fitted relative to the current conductor 116 and the hole 120 such that the sensor elements of the magnetic field sensor are arranged in such a way in relation to an edge 120a of the hole 120, which extends parallel to the direction of current flow of the current conductor, that one of the sensor elements, sensor element 20, overlaps the current conductor 116 in a plan view of the current conductor 116 and the other of the sensor elements, sensor element 22, does not overlap the current conductor 116 in a plan view of the current conductor 116. The front side of the sensor chip is oriented downward (face down). In other words, the sensor chip is located on the side of the connection frame facing the current conductor.

The edge 120a of the straight section of the current conductor 116, in relation to which the sensor elements are arranged, is thus formed by the hole 120 through the current conductor 116. Since the hole is completely surrounded by material of the current conductor in a plan view, e.g., is closed, the edge 120a is an inner edge of the current conductor 120. In FIG. 11A, the direction of current flow through the current conductor 116 is in turn the Y direction, while the sensitive direction of the sensor elements, in which they detect a magnetic field, is the X direction.

The hole 120 divides the current conductor into two parts, a first part which has the edge 120a and is also referred to here as the first part of the current conductor 116, and a second part, which has an opposite edge 120b formed by the hole 120 and is also referred to here as the second part of the current conductor.

The magnetic field sensor 10 is thus arranged to measure a current which flows through the first part of the current conductor 116, which has the edge 120a. In order to reduce the influence of a current, which flows through the second part of the current conductor 116, on the current measurement, the hole 120 may have such a size that a distance of the sensor element 22 from the opposite edge 120b is greater than a distance of the sensor element from the edge 120a. In the example shown, this distance is approximately four times greater. In general, in examples, the distance from the edge 120b may be more than twice as large, more than three times larger, or more than four times larger than the distance from the edge 120a.

In the example shown, the hole 120 is arranged transversely to the direction of current flow centrally in the current conductor 116, so that a symmetrical current flow through the first and the second part of the current conductor results. In other examples, the hole may also be offset from the center. The position of the hole can bring about different parts of the current flow, which flow through the two parts of the current conductor. This can be taken into account when evaluating the magnetic field detected by the magnetic field sensor 10.

In the example shown, the current conductor 116 is again shown as a current conductor which is formed in three layers of a PCB, wherein it is clear however that, as in the other examples described here, the current conductor may be formed by a single layer or a different number of layers of a PCB.

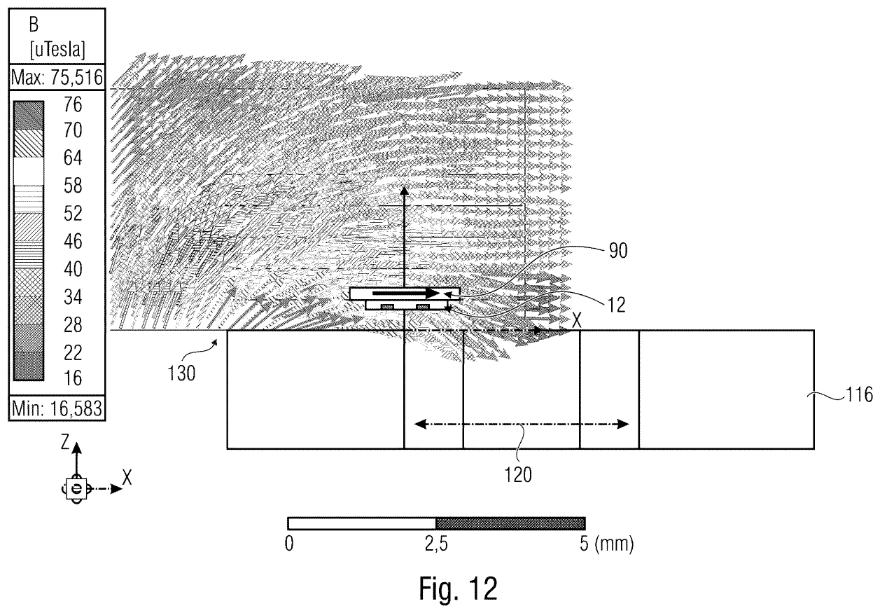

FIG. 12 shows a representation of a field line distribution of a magnetic field, which is generated by a current that flows in the direction of current flow, Y direction, through the current conductor 116. FIG. 12 schematically shows the sensor chip 12. At the location of the sensor chip, a strong lateral magnetic field prevails in the sensitive direction of the sensor elements, as schematically illustrated by an arrow 90 in FIG. 12. However, due to the hole 120 in the region of the sensor chip 10, only very small vertical magnetic field components are present, which leads to fewer eddy currents being induced in the connection frame of the magnetic field sensor 10. In contrast, a stronger vertical field prevails at an outer edge 130 of the conductor 116, which would lead to significantly higher eddy currents, which are induced in the connection frame of the magnetic field sensor, if the sensor 10 is positioned at this edge 130. By positioning the sensor at the edge of the hole formed in the current conductor, distortions which are generated in the output signal of the differential magnetic field sensor due to eddy currents in the connection frame of the magnetic field sensor can therefore be reduced.

In examples, the width of the hole 120 transversely to the direction of current flow through the current conductor is at least so large that the sensor 10 or at least the connection frame 14 of same does not overlap the second part of the current conductor 116 in a plan view. In other words, the width of the hole is at least half the width of the connection frame 14. This enables low vertical magnetic field components across the entire width of the connection frame transversely to the direction of current flow. Furthermore, an influence of a current flowing through the second part on the magnetic field detected by the magnetic field sensor 10 can be reduced and in the best case prevented.

In examples, the length of the hole in the direction of current flow is equal to or greater than a dimension of the connection frame in the direction of current flow. This enables low vertical magnetic field components over the length of the connection frame in the direction of current flow.

In examples, an outer contour of the current conductor is adapted to compensate at least to some extent for a reduction of a cross-sectional area of the current conductor perpendicular to the direction of current flow due to the hole. For example, the current conductor 116 shown in FIGS. 11A and 11B has widenings 140 on both sides at least in the region of the hole 120 in order to keep the cross section of the conductor, through which the current can flow, substantially constant. This supports a more even current flow through the current conductor even in the region of the hole 120. Thus, the outer contour of the current conductor 116 in the region of the hole 120 has a larger width than in other regions of the current conductor 116. In alternative examples, a thickness of the current conductor in the region of the hole 120 could also be increased, which may however be more difficult to implement for production reasons.

In examples, the hole formed in the current conductor may be empty. In general, the hole formed in the current conductor may be filled with a non-conductive material, such as a dielectric. In examples, the non-conductive material may be a non-conductive material from which the PCB is formed, such as an epoxy resin. The hole can therefore also be referred to as a non-conductive insert in the current conductor.

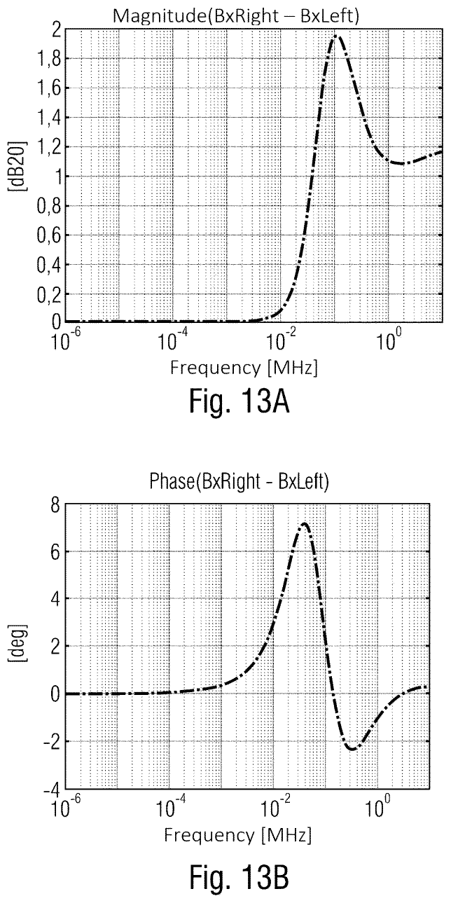

FIGS. 13A and 13B show simulation results which show the magnitude and phase of simulated magnetic field measurements using a current measuring device as shown in FIGS. 11A and 11B. For the simulations, an example current conductor with a width of 5 mm, which is divided by the hole into two partial tracks with a width of 2.5 mm each, was used with a hole with a width of 3 mm. A comparison of FIG. 13A with FIG. 2C clearly shows a smaller deviation of the magnitude due to the hole in the current conductor, at the edge of which the magnetic field sensor is placed, namely from almost 7 dB20 in FIG. 2C to less than 2 dB20 in FIG. 13A. FIG. 13B also shows a transfer characteristic of the phase, which deviates significantly less from the behavior shown in FIG. 2B than the transfer characteristic in FIG. 2D. With regard to the temporal response, a similar result can be obtained using examples in which a hole is provided in the current conductor for reducing eddy currents induced in the connection frame, as shown for the compensation layer in FIGS. 9A to 9B.

Although examples have been described above which have either a compensation layer or a hole in the current conductor, examples may also have a combination of both devices. In such a case, the compensation layer would be arranged according to the above description in relation to the current conductor and magnetic field sensor, with the exception that the magnetic field sensor would not be arranged on an outer edge of the current conductor, but on an edge of the hole, that is to say an inner edge of the current conductor.

It should be noted that in examples, due to the compensation layer, the phase error does not improve overall over the entire frequency range from 1 MHz to 10 MHz. In this respect, it should be noted that certain applications do not require the full bandwidth up to 10 MHz. For example, at a frequency in the range of 20 kHz, a lower phase error than in FIG. 2B can be seen in all of the characteristics shown in FIGS. 5C to 8C. For example, FIG. 13B shows an improvement of the phase over large parts of the frequency range.

In examples, the device for reducing distortions which are generated in an output signal of the differential magnetic field sensor due to eddy currents in the connection frame of the magnetic field sensor may be configured to reduce the influence of such eddy currents on the magnitude of the measured magnetic field at a certain frequency, for example 100 kHz, by 30% or more compared to a case in which the device is not provided.

In all examples, the sensor chip is preferably centered above the edge of the current conductor. However, due to tolerances and mounting inaccuracies, the sensor chip may also be arranged offset from the edge, for example, with an offset of up to 300 um in each direction. Simulations have shown that the effects described here also occur in sensor chips arranged in such an offset manner.

In examples, the thickness of the sensor chip 12, e.g., the distance between connection frame and sensor element, TMR sensor, can be between 100 μm and 300 μm, wherein simulations have shown that the effects described here apply for such chip thicknesses. In examples, the thickness of the sensor chip is 150 μm. In examples, the distance between the two sensor elements of the magnetic field sensor can be in the range of 0.5 to 2 mm. In examples, the distance is 1.2 mm.

The current measuring technologies described here are suitable for many industrial and automotive applications. They are particularly applicable for any application that requires high accuracy and fast input signals. A typical application is an eFUSE or an electrical circuit interrupter.

### Aspects

Further aspects of the disclosure are set forth below:

Aspect 1: A current measuring device having the following features; a current conductor, a differential magnetic field sensor which has a connection frame and two sensor elements, wherein the sensor elements are arranged such in relation to an edge of a straight section of the current conductor, which is parallel to a direction of current flow through the current conductor, that one of the sensor elements overlaps the current conductor in a plan view of the current conductor and the other of the sensor elements does not overlap the current conductor in a plan view of the current conductor; and a device for reducing distortions which are generated in an output signal of the differential magnetic field sensor due to eddy currents in the connection frame of the magnetic field sensor.

Aspect 2: The current measuring device according to aspect 1, in which the sensor elements are arranged symmetrically to the edge of the straight section of the current conductor.

Aspect 3: The current measuring device according to aspect 1 or 2, in which the device for reducing distortions has a layer made from an electrically conductive non-magnetic material which is arranged on the side of the connection frame facing the current conductor.

Aspect 4: The current measuring device according to aspect 3, in which the layer has a smaller thickness than the connection frame in a direction perpendicular to a plane in which the current conductor is arranged.

Aspect 5: The current measuring device according to aspect 3 or 4, in which the layer is formed from copper and/or aluminum.

Aspect 6: The current measuring device according to any one of aspects 3 to 5, in which the layer is arranged, at least in sections, between the current conductor and the connection frame.

Aspect 7: The current measuring device according to any one of aspects 3 to 6, in which the layer is arranged such that it overlaps the connection frame of the magnetic field sensor completely in a plan view.

Aspect 8: The current measuring device according to any one of aspects 3 to 7, in which the layer is formed to generate eddy currents in same using a magnetic field which is generated by the current flow through the current conductor, which eddy currents generate a magnetic field in a sensitive direction of the magnetic field sensor, which magnetic field counteracts a magnetic field in the region of the sensor elements of the magnetic field sensor, which is generated by eddy currents which are generated in the connection frame by the magnetic field which is generated by the current flow through the current conductor.

Aspect 9: The current measuring device according to any one of aspects 3 to 8, in which the layer is structured and has breaks in the form of holes or slits.

Aspect 10: The current measuring device according to aspect 9, in which the layer has breaks in the region of the sensor elements of the magnetic field sensor.

Aspect 11: The current measuring device according to any one of aspects 1 to 10, in which the device for reducing distortions has a hole through the current conductor, wherein the edge of the straight section of the current conductor, in relation to which edge the sensor elements are arranged, is formed by the hole through the current conductor, wherein the other of the sensor elements is arranged above the hole in a plan view of the current conductor.

Aspect 12: The current measuring device according to aspect 11, in which the hole is filled with a non-conductive material.

Aspect 13: The current measuring device according to aspect 11 or 12, in which the hole is arranged transversely to the direction of current flow centrally in the current conductor.

Aspect 14. The current measuring device according to any one of aspects 11 to 13, in which a length of the hole in the direction of current flow is equal to or greater than a dimension of the connection frame in the direction of current flow and/or in which a width of the hole transversely to the direction of current flow is equal to or greater than half the width of the connection frame.

Aspect 15. The current measuring device according to any one of aspects 11 to 14, in which an outer contour of the current conductor is adapted to compensate at least to some extent for a reduction of a cross-sectional area of the current conductor perpendicular to the direction of current flow due to the hole.

Aspect 16. The current measuring device according to aspect 15, in which the outer contour of the current conductor in the region of the hole has a greater width than in other regions of the current conductor.

Even though some aspects of the present disclosure have been described as features in conjunction with a device, it is evident that such a description may likewise be considered to be a description of corresponding method features. Even though some aspects have been described as features in conjunction with a method, it is evident that such a description may also be considered to be a description of corresponding features of a device or of the functionality of a device.

In the above detailed description, in some cases different features have been grouped together in examples in order to rationalize the disclosure. This kind of disclosure should not be interpreted as being intended for the claimed examples to have more features than specified expressly in each claim. Rather, as set forth in the following claims, the subject matter may be present in less than all of the features of a single disclosed example. The following claims are therefore hereby incorporated into the detailed description, wherein each claim may exist as a standalone separate example. While each claim may exist as a standalone separate example, it is pointed out that, although dependent claims in the claims refer back to a specific combination with one or more other claims, other examples also comprise a combination of dependent claims with the subject matter of any other dependent claim or a combination of any feature with other dependent or independent claims. Such combinations are included, unless it is stated that a specific combination is not intended. It is furthermore also intended for a combination of features of a claim with any other independent claim to be included, even if this claim is not directly dependent on the independent claim.

The examples described above merely illustrate the principles of the present disclosure. It should be understood that modifications and variations of the arrangements and of the details which are described are obvious to those skilled in the art. Therefore, the disclosure is intended to be limited only by the appended patent claims and not by the specific details that are presented for the purpose of describing and explaining the examples.

1. A current measuring device, comprising:
a current conductor;
a differential magnetic field sensor which has a connection frame and two sensor elements, wherein the sensor elements are arranged such in relation to an edge of a straight section of the current conductor, which is parallel to a direction of current flow through the current conductor, that one of the sensor elements overlaps the current conductor in a plan view of the current conductor and the other of the sensor elements does not overlap the current conductor in a plan view of the current conductor; and
a device for reducing distortions which are generated in an output signal of the differential magnetic field sensor due to eddy currents in the connection frame of the magnetic field sensor.

2. The current measuring device as claimed in claim 1, wherein the sensor elements are arranged symmetrically to the edge of the straight section of the current conductor.

3. The current measuring device as claimed in claim 1, wherein the device for reducing distortions has a layer made from an electrically conductive non-magnetic material which is arranged on a side of the connection frame facing the current conductor.

4. The current measuring device as claimed in claim 3, wherein the layer has a smaller thickness than the connection frame in a direction perpendicular to a plane in which the current conductor is arranged.

5. The current measuring device as claimed in claim 3, wherein the layer is formed from copper and/or aluminum.

6. The current measuring device as claimed in claim 3, wherein the layer is arranged, at least in sections, between the current conductor and the connection frame.

7. The current measuring device as claimed in claim 3, wherein the layer is arranged such that it overlaps the connection frame of the magnetic field sensor completely in a plan view.

8. The current measuring device as claimed in claim 3, wherein the layer is formed to generate eddy currents in same using a magnetic field which is generated by the current flow through the current conductor, which eddy currents generate a magnetic field in a sensitive direction of the magnetic field sensor, which magnetic field counteracts a magnetic field in a region of the sensor elements of the magnetic field sensor, which is generated by eddy currents which are generated in the connection frame by the magnetic field which is generated by the current flow through the current conductor.

9. The current measuring device as claimed in claim 3, wherein the layer is structured and has breaks in the form of holes or slits.

10. The current measuring device as claimed in claim 9, wherein the layer has breaks in a region of the sensor elements of the magnetic field sensor.

11. The current measuring device as claimed in claim 1, wherein the device for reducing distortions has a hole through the current conductor, wherein the edge of the straight section of the current conductor, in relation to which edge the sensor elements are arranged, is formed by the hole through the current conductor, wherein the other of the sensor elements is arranged above the hole in a plan view of the current conductor.

12. The current measuring device as claimed in claim 11, wherein the hole is filled with a non-conductive material.

13. The current measuring device as claimed in claim 11, wherein the hole is arranged transversely to the direction of current flow centrally in the current conductor.

14. The current measuring device as claimed in claim 11, wherein a length of the hole in the direction of current flow is equal to or greater than a dimension of the connection frame in the direction of current flow, and/or
wherein a width of the hole transversely to the direction of current flow is equal to or greater than half the width of the connection frame.

15. The current measuring device as claimed claim 11, wherein an outer contour of the current conductor is adapted to compensate at least to some extent for a reduction of a cross-sectional area of the current conductor perpendicular to the direction of current flow due to the hole.

16. The current measuring device as claimed in claim 15, wherein the outer contour of the current conductor in a region of the hole has a greater width than in other regions of the current conductor.
